(19) United States
(12) Patent Application Publication
(10) Pub. No.: US 2026/0173543 A1
(43) Pub. Date: Jun. 18, 2026

(54) SOLAR PANEL DISASSEMBLING APPARATUS

(71) Applicant: WON KWANG S&T CO., LTD., Incheon (KR)

(72) Inventors: SANG HUN LEE, Incheon (KR); TAE HEUN LEE, Incheon (KR)

(21) Appl. No.: 19/125,911

(22) PCT Filed: Feb. 14, 2024
(86) PCT No.: PCT/KR2024/002108

§ 371 Date: Apr. 30, 2025

(30) Foreign Application Priority Data
Feb. 17, 2023 (KR) 10-2023-0021546

(51) Int. Cl. H10F 19/80; B32B 43/00; F24S 25/00; H02S 20/10; H02S 20/23; H02S 30/10; H02S 30/20; H02S 40/34

(52) U.S. Cl. CPC H10F 19/80; B32B 43/006; H02S 20/10; H02S 20/23; H02S 30/10; H02S 30/20; H02S 40/34; F24S 2025/012

(57) ABSTRACT

A solar panel disassembling apparatus includes a supporting plate that supports the bottom of a solar panel so that the top surface thereof is in contact with a glass plate, a moving scraper module that includes a first body, a first elevator, and a blade connected to the first elevator and changing in height with respect to the supporting plate for scraping the stacked film, a moving pressing module that includes a second body, a second elevator, and a pressing unit connected to the second elevator and changing in height with respect to the supporting plate, that is disposed forward in the forward movement direction of the moving scraper module, and that presses and aligns the stacked film using the pressing unit ahead of the moving scraper module, and a bending guide plate disposed over the blade, and rolling and keeping therein the stacked film separated from the blade.

### BACKGROUND

### 1. Technical Field

The present disclosure relates to a solar panel disassembling apparatus for disassembling a solar panel (which is the part left after the exterior such as a frame is separated from a common solar module) and, more particularly, to a solar panel disassembling apparatus that can precisely disassemble a solar panel into a glass plate and remaining film type stack that is not the glass plate.

### 2. Background Art

The development of clean energy that reduces environment pollution is being accelerated. Development of clean energy is in progress in various ways including national support projects. Clean energy technology variously includes not only a technology of managing produced power such as energy management, delivery, and storage, but a renewable energy technology that uses biomass, etc. Solar photovoltaic power generation, wind power generation, etc. that generate power using natural force without using the fossil fuel have been continuously studied as power production technologies.

In particular, solar photovoltaic power generation has been remarkably improved in power generation efficiency through continuous improvement of the technology since development, and accordingly, it is considered as a spotlighted alternative energy technology even at present. Solar photovoltaic power generation facilities are continuously increasing because there is the advantage that they can be easily applied even to places where conventional power generation facilities, etc. are difficult to install, they hardly cause environmental damage, and it is possible to use existing buildings, facilities, etc. when installing them.

However, a solar photovoltaic power generation facility also has a problem with maintenance because a solar cell has to be replaced and discarded when its lifespan is ended. In particular, as not only the number, but the application unit or area of solar photovoltaic power generation facilities are increased, it is required to replace and discard solar cells in large quantities. However, most solar photovoltaic power generation facilities are aggregate of photovoltaic modules formed by combining a solar cell to a frame. Further, since photovoltaic modules have a structure in which a glass plate, etc. are bonded to solar cells, they are difficult to simply discard, which is a considerable problem in management of solar photovoltaic power generation facilities in a large scale.

In particular, it is considerably difficult to disassemble and dispose of a solar panel (which is an inner panel composed of a glass plate and a film type stack including solar cells stacked on the glass plate) which is left after the exterior is removed when a solar module is discarded. Even if an exterior such as a frame is appropriately removed, it is difficult to cleanly remove the film type stack bonded to the glass plate and a problem that the glass plate is damaged due to an inappropriate process is easily generated. Accordingly, measures for solving this problem are continuously required. As related prior art, there is Korean Patent Application Publication No. 10-2021-0083721 (Jul. 7, 2021)

### SUMMARY

The present disclosure has been made in an effort to solve the problems and an objective of the present disclosure is to provide a solar panel disassembling apparatus that can precisely disassemble a solar panel into a glass plate and a film type stack.

The object of the present disclosure is not limited to those described above and other objects may be made apparent to those skilled in the art from the following description.

A solar panel disassembling apparatus that is configured to separate a glass plate by removing a stacked film from a solar panel composed of the glass plate and the stacked film including solar cells stacked on the glass plate, includes: a supporting plate that supports the bottom of a solar panel so that the top surface thereof is in contact with a glass plate; a moving scraper module that includes a first body connected to a guide and moving in parallel with the supporting plate, a first elevator coupled to the first body to be movable up and down and moving up and down perpendicular to the movement direction of the first body, and a blade disposed over the supporting plate, connected to the first elevator, and changing in height with respect to the supporting plate when the first elevator is operated, and that scrapes the stacked film using the blade while moving forward in parallel with the supporting plate; a moving pressing module that includes a second body connected to a guide and moving in parallel with the supporting plate, a second elevator coupled to the second body to be movable up and down and moving up and down perpendicular to the movement direction of the second body, and a pressing unit disposed over the supporting plate, connected to the second elevator, and changing in height with respect to the supporting plate when the second elevator is operated, that is disposed forward in the forward movement direction of the moving scraper module, and that presses and aligns the stacked film using the pressing unit ahead of the moving scraper module when the moving scraper module is moved forward; and a bending guide plate composed of a bending plate, disposed over the blade, and rolling and keeping therein the stacked film separated from the blade.

The bending guide plate may have an accommodation space in which the stacked film is accommodated at a center because the bending plate is rolled such that a radius of curvature gradually decreases.

The bending guide plate may have an opening being open downward toward the blade between parts of the bending plate, and is rolled once or more, so the accommodation space may not be exposed to the outside.

The solar panel disassembling apparatus may further include a gas spray cooling the stacked film passing through between the blade and the bending guide plate by spraying gas to the stacked film.

The gas spray may guide the stacked film to the opening of the bending guide plate by pressing the stacked film.

The gas spray may spray the gas at a temperature below a melting point of the stacked film.

The gas spray may spray the gas through a slit formed along and parallel with the blade.

The moving pressing module may further include a heating unit that induces thermal deformation of the stacked film by heating the outer surface of the stacked film.

The pressing unit may include a plurality of supporting rollers spaced apart from each other in rolling contact with the outer surface of the stacked film, and the heating unit may be a heater that radiates heat to a space between the supporting rollers in the pressing unit.

The pressing unit may include a plurality of supporting rollers spaced apart from each other in rolling contact with the outer surface of the stacked film, and the heating unit may be a heater that radiates heat to a space between the supporting rollers in the pressing unit.

The solar panel disassembling apparatus may further include: a load cell that is disposed under the solar panel at a start position where the blade starts to come in contact with the solar panel; and a controller that brings the blade in close contact with the solar panel by moving down the first elevator at the start position and that adjusts the position of the blade by controlling the operation of the first elevator in accordance with at least any one of magnitude and a variation of load sensed by the load cell.

According to the present disclosure, it is possible to precisely disassemble a solar panel remaining after the exterior such as a frame is removed from a common solar module into a glass plate and a film-type stack. In particular, it is possible to accurately find out the bonding point between the glass plate and the stack and disassemble the solar panel, so disassembling is possible without substantial damage to the glass plate. Further, it is possible to cleanly separate the glass plate and the stack by inducing thermal deformation of the stack, and the separated parts can be very conveniently recycled. Further, since the disassembling process is very conveniently and quickly performed, it is possible to improve the efficiency of the entire process of disposing of a waste solar module.

### BRIEF DESCRIPTION OF THE DRAWINGS

FIG. 1 is a perspective view of a solar panel disassembling apparatus according to an embodiment of the present disclosure;

FIG. 2 is a side view of the solar panel disassembling apparatus of FIG. 1;

FIG. 3 is an enlarged view of a moving scraper module of the solar panel disassembling apparatus of FIG. 1;

FIGS. 4 and 5 are operation views showing the structure of a bending guide plate and an operation of a roller that are disposed in the moving scraper module of FIG. 3;

FIG. 6 is an enlarged view showing the moving scraper module of FIG. 3 with the bending pressing plate and the pressing roller removed;

FIG. 7 is an operation view showing an operation of adjusting the position of a blade disposed in the moving scraper module of FIG. 6;

FIG. 8 is an enlarged view of a moving pressing module of the solar panel disassembling apparatus of FIG. 1;

FIG. 9 is a cross-sectional view showing the internal structure of the moving pressing module of FIG. 8;

FIG. 10 is a view showing an operation of disassembling a solar panel by the solar panel disassembling apparatus of FIG. 1;

FIGS. 11A to 11E are views showing in more detail an operation of the bending pressing plate in the disassembling operation of FIG. 10;

FIG. 12 is a view showing an operation after disassembling a solar panel by the solar panel disassembling apparatus of FIG. 1.

### DETAILED DESCRIPTION

The advantages and features of the present disclosure, and methods of achieving them will be clear by referring to the exemplary embodiments that will be described hereafter in detail with reference to the accompanying drawings. However, the present disclosure is not limited to the exemplary embodiments described hereafter and may be implemented in various ways, and the exemplary embodiments are provided to complete the description of the present disclosure and let those skilled in the art completely know the scope of the present disclosure and the present disclosure is defined by claims. Like reference numerals indicate the same components throughout the specification.

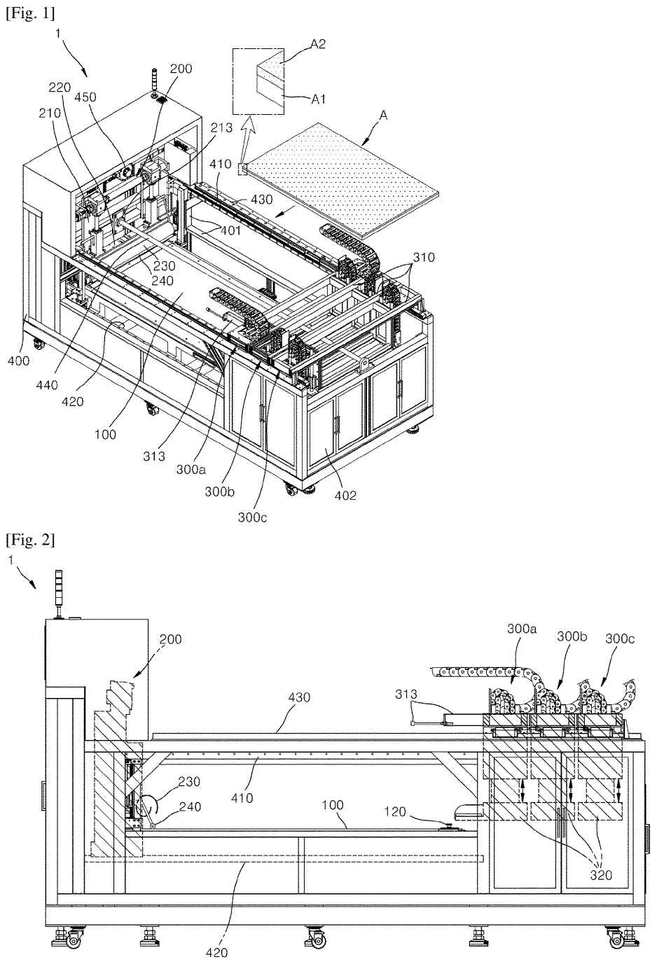

Hereafter, a solar panel disassembling apparatus according to the present disclosure is described in detail with reference to FIGS. 1 to 12.

FIG. 1 is a perspective view of a solar panel disassembling apparatus according to an embodiment of the present disclosure, and FIG. 2 is a side view of the solar panel disassembling apparatus of FIG. 1.

Referring to FIGS. 1 and 2, a solar panel disassembling apparatus 1 according to the present disclosure includes a supporting plate 100, a moving scraper module 200 moving in parallel along the supporting plate 100, moving pressing modules 300a, 300b, and 300c, and a bending guide plate 230. A solar panel A that is the target to be disassembled is mounted on the supporting plate 100, and the moving scarper module 200 and the moving pressing modules 300a, 300b, and 300c separately move and come in contact with the solar panel A.

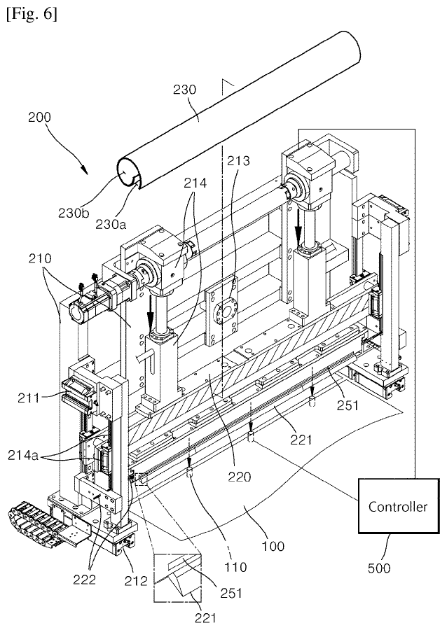

The moving scraper module 200 scrapes out the portion (i. e., a stacked film A2) that is not a glass plate A1 of the solar module A using a blade (see 221 in FIG. 6), and the moving pressing modules 300a, 300b, and 300c align the portion (stacked film A2) ahead of the moving scraper module 200. Accordingly, the solar panel A formed by bonding the glass plate A1 and the stacked film A2 that is not the glass plate can be cleanly disassembled into two parts by the interaction of the moving pressing modules 300a, 300b, and 300c and the moving scraper module 200.

In particular, the bending guide plate 230 that rolls and keeps the separated stacked film A2 therein is formed over the blade 221. The bending guide plate 230 has a rolled structure, and rolls and keeps a film layer (stacked film) in the internal space thereof, so it becomes very convenient to handle a film layer.

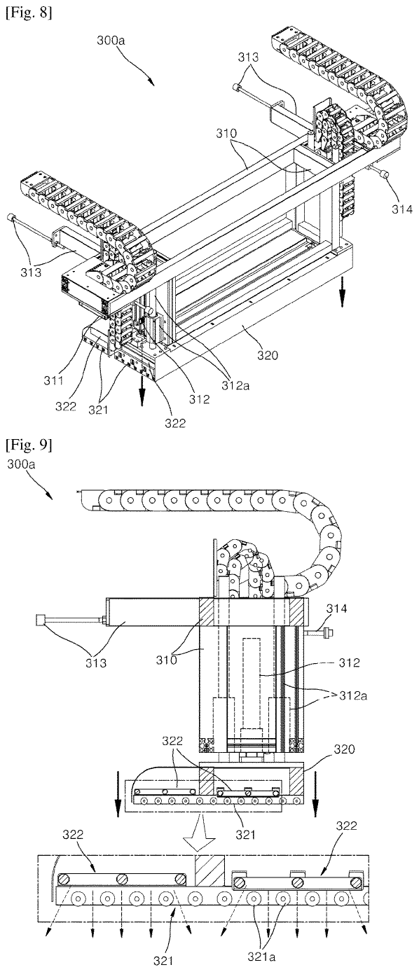

The solar panel disassembling apparatus 1 of the present disclosure is configured as follows. The solar panel disassembling apparatus 1, which is configured to separate a glass plate A1 by removing a stacked film A2 from a solar panel A composed of the glass plate A1 and the stacked film A2 including solar cells stacked on the glass plate, includes: a supporting plate 100 that supports the bottom of a solar panel so that the top surface thereof is in contact with a glass plate; a moving scraper module 200 that includes a first body 210 connected to a guide and moving in parallel with the supporting plate 100, a first elevator 220 coupled to the first body 210 to be movable up and down and moving up and down perpendicular to the movement direction of the first body 210, and a blade (see 221 in FIG. 6) disposed over the supporting plate 100, connected to the first elevator 220, and changing in height with respect to the supporting plate 100 when the first elevator 220 is operated, and that scrapes the stacked film A2 using the blade 221 while moving forward in parallel with the supporting plate 100; moving pressing modules 300a, 300b, and 300c that includes a second body 310 connected to a guide and moving in parallel with the supporting plate 100, a second elevator (see 320 in FIG. 8) coupled to the second body 310 to be movable up and down and moving up and down perpendicular to the movement direction of the second body 310, and a pressing unit (see 321 in FIG. 8) disposed over the supporting plate 100, connected to the second elevator 320, and changing in height with respect to the supporting plate 100 when the second elevator 320 is operated, that is disposed forward in the forward movement direction of the moving scraper module 220, and that presses and aligns the stacked film A2 using the pressing unit 321 ahead of the moving scraper module when the moving scraper module 200 is moved forward, and a bending guide plate 230 composed of a bending plate, disposed over the blade 223, and rolling and keeping therein the stacked film A2 separated from the blade 221.

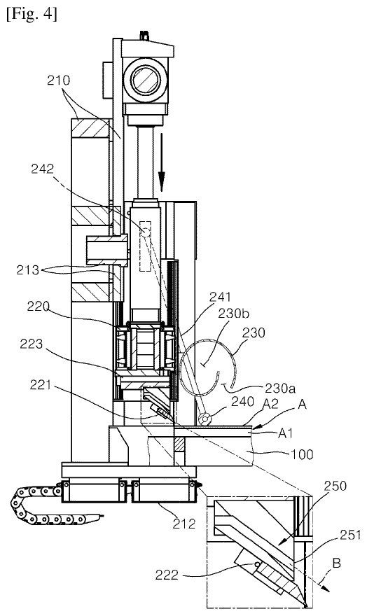

In an embodiment of the present disclosure, the bending guide plate 230 may have an accommodation space (see 230b in FIG. 4) in which the stacked film A2 is accommodated at the center because the bending plate forming the bending guide plate is rolled such that the radius of curvature gradually decreases. Further, the bending guide plate 230 may have an opening (see 230a in FIG. 4) being open downward toward the blade 221 between parts of the bending plate and is rolled once or more, so the accommodation space may not be exposed to the outside.

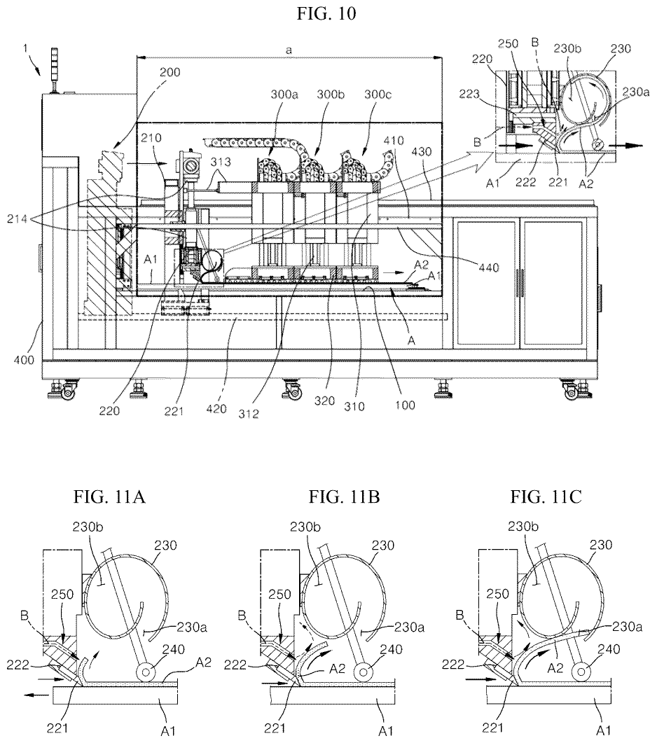

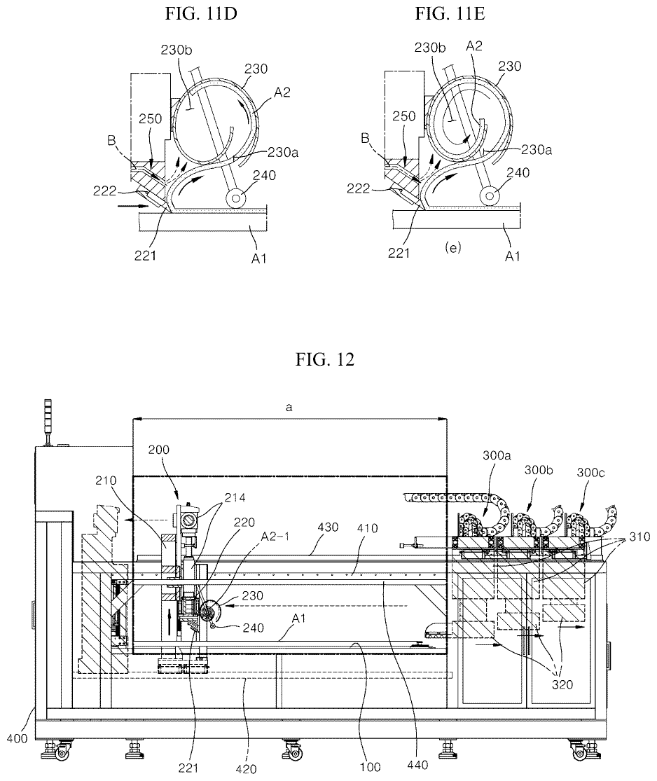

Further, the solar panel disassembling apparatus 1 may further include a gas spray (see 250 in FIG. 4) that cools the stacked film A2 passing through between the blade 221 and the bending guide plate 230 by spraying gas to the stacked film A2, and the gas spray 250 can guide the stacked film A2 to the opening 230a of the bending guide plate 230 by pressing the stacked film A2 (see the operation in FIGS. 11A to 11E).

Further, the plurality of moving pressing modules 300a, 300b, and 300c may be separably coupled to each other and may be continuously disposed forward in the forward movement direction of the moving scraper module 200, and each may include a heating unit (see 322 in FIGS. 8 and 9) that induces thermal deformation of the stacked film A2 by heating the outer surface of the stacked film A2.

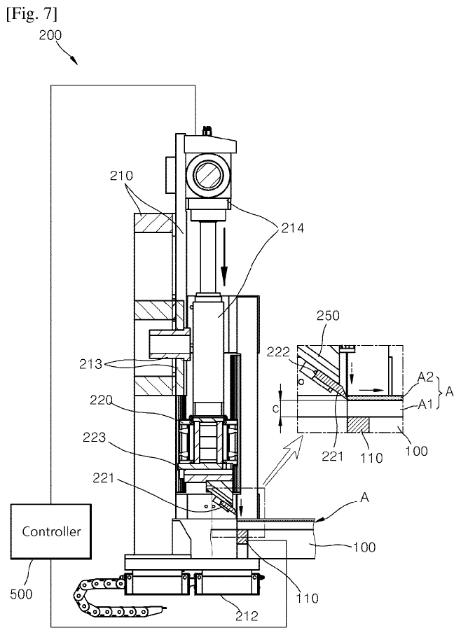

Further, a load cell (see 110 in FIGS. 6 and 7) that is disposed under the solar panel A at a start position where the blade 221 starts to come in contact with the solar panel A; and a controller (see 500 in FIGS. 6 and 7) that brings the blade 221 in close contact with the solar panel A by moving down the first elevator 220 at the start position and that adjusts the position of the blade 221 by controlling the operation of the first elevator 220 in accordance with at least any one of the magnitude and the variation of load sensed by the load cell 110. The configuration, operation effect, etc. of the present disclosure are described hereafter in more detail on the basis of the embodiment of the present disclosure.

First, the solar panel A that is the target to be disposed of in the present disclosure is briefly described with reference to FIG. 1. The solar panel A may be a part left after the exterior such as a frame (a bar-shaped protection structure coupled to the edge of a solar module) and a junction box (a structure for cable connection attached to the outer side of a stacked film, that is, the rear surface of a solar module) is removed from a common solar module. The solar panel A, which is the part where power is actually generated in a solar module, may be composed of a stacked film A2 including solar cells, and a glass plate A1 supporting the stacked film A2. The solar panel A may be a panel having an entirely rectangular shape and the cross-section thereof may be a layered structure including the glass plate A1 and the stacked film A2 including solar cells stacked on the glass plate A1. The solar panel A may be largely divided into a layer of the glass plate A1 and a layer of the stacked film A2 bonded to the layer of the glass plate A1. Solar cells are included in the stacked film A2, and an encapsulation film, a back sheet, etc. that are disposed on both sides of the solar cell may be included together in addition to the solar cells. The solar panel disassembling apparatus 1 of the present disclosure is an apparatus that disassembles the solar panel A into the glass plate A1 and the stacked film A2.

The solar panel disassembling apparatus 1 may include a housing 400 as a supporting structure. Other components of the present disclosure may be disposed in the housing 400. The housing 400, for example, may be formed by combining metallic frames, metallic plates, or the like, and may provide a base or a frame that supports other components. The housing 400 may be partially open and closed to take in and out an object and to protect the inside. For example, an opening 401 for taking in and out the solar panel A or the glass plate A1 left after disassembling may be formed on a side of the housing 400, and a door 402 may be formed on the other side. The housing 400 is not necessarily limited to this shape, so it can be modified in various shapes, if necessary.

One or more guides may be disposed at the housing 400. The guide can guide movement of the moving scraper module 200 and the moving pressing modules 300a, 300b, and 300c and can determine the movement directions of them. The forward movement direction to be described below may be a direction that is parallel with the guide. For example, the guide may include a third guide bar 430 disposed at the top of the housing 400, a first guide bar 410 disposed slightly lower than or at the same height as the third guide bar 430, and a second guide bar 420 disposed at a lower portion lower than the third guide bar 430 in the housing 400. The guide bars each may be disposed at least in a pair. The guide bars are arranged in the same direction, as shown in the figures.

A driving structure that provides power to the moving scraper module 200 and the moving pressing modules 300a, 300b, and 300c may be formed using the housing 400. When the driving structure is formed by combining a plurality of components, some of the components may be disposed in the housing 400. For example, the driving structure may include a driving shaft 440 disposed across the housing 400 and in parallel with the guide. The driving shaft 440 is coupled to a driving block 213 of the moving scraper module 220, whereby a linear actuator such as a ball screw can be configured (in this case, a thread may be formed on the driving shaft and ball bearing engaging with the thread may be formed at the driving block). The driving motor 450 disposed in the housing 400 can move the moving scraper module 200 in parallel with the driving shaft 440 by rotating the driving shaft 440 (in this case, a power transmission device such as a belt, a chain, etc. may be used). The moving pressing modules 300a, 300b, and 300c can be moved together by the driving force provided to the moving scraper module 200. However, the present disclosure is not necessarily limited to this configuration, and the way of supplying power to the moving scraper module 200 and the moving pressing modules 300a, 300b, and 300c may be freely changed.

The supporting plate 100 is horizontally disposed in the housing 400. The top of the supporting plate 100 is formed to be flat. The supporting plate 100 may be installed low close to the bottom of the housing 400 and may be positioned close to the opening 401 described above. The supporting plate 100 supports the bottom of the solar panel A so that the top surface thereof is in contact with the glass plate A1. That is, the solar panel A is horizontally mounted on the supporting plate 100 with the glass plate A1 facing down and the stacked film A2 facing up. This situation is exemplified in FIG. 1, and the solar panel A mounted on the supporting plate 100 overlap the supporting plate 100.

A load cell (see 110 in FIGS. 6 and 7) to be described below may be disposed at a first end of the supporting plate 100. A stopper (see 120 in FIG. 2) that fixes the solar panel A may be disposed at a second end of the supporting plate 100. The moving scraper module 200 can move forward in close contact with the solar panel A at least from the first end of the supporting plate 100 where the load cell 110 is positioned to the second end of the supporting plate 100 where the stopper 120 is positioned (see FIG. 10). Accordingly, such direction is the forward movement direction of the moving scraper module 200 (indicated by the arrow towards the right side in FIG. 10). The moving pressing modules 300a, 300b, and 300c also move forward in the same direction in close contact with the solar panel A and are positioned ahead of the moving scraper module 200 in the forward movement direction (i.e., further ahead in the forward movement direction). The moving scraper module 200, as shown in FIG. 2, can move back outside the supporting plate 100 before operating, and accordingly, can prepare the moving pressing modules 300a, 300b, and 300c by pushing them to the first end of the supporting plate 100. That is, before starting to operate, the moving pressing modules 300a, 300b, and 300c are moved right in front of the moving scraper module 200 shown in FIG. 2, whereby they can be prepared substantially in close contact with the moving scraper module 200. The detailed operation will be described in more detail below.

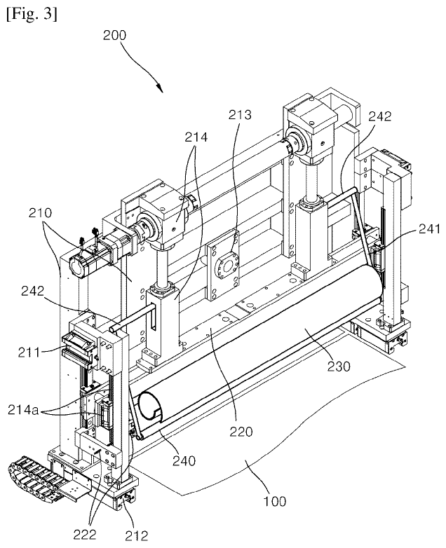

Referring to FIG. 1, the moving scraper module 200 includes: a first body 210 connected to a guide and moving in parallel with the supporting plate 100; a first elevator 220 coupled to the first body 210 to be movable up and down and moving up and down perpendicular to the movement direction of the first body 210; and a blade 221 disposed over the supporting plate 100, connected to the first elevator 220, and changing in height with respect to the supporting plate 100 when the first elevator 220 is operated. The moving scraper module 200 having this configuration scrapes out the stacked film A2 from the solar panel A using the blade (see 221 in FIG. 6) while moving forward in parallel with the supporting plate 100 (see the enlarged view of FIG. 10). In more detail, the moving scraper module 200 can disassemble the solar panel A into two part by cutting the bonding position between the glass plate A1 and the stacked film A2 using the blade 221. Hereafter, the operation of moving scraper module 200 is described in more detail with reference to FIGS. 3 to 7.

FIG. 3 is an enlarged view of a moving scraper module of the solar panel disassembling apparatus of FIG. 1, and FIGS, 4 and 5 are operation views showing the structure of a bending guide plate and an operation of a roller that are disposed in the moving scraper module of FIG. 3, FIG. 6 is an enlarged view showing the moving scraper module of FIG. 3 with the bending pressing plate and the pressing roller removed, and FIG. 7 is an operation view showing an operation of adjusting position of a blade disposed in the moving scraper module of FIG. 6. The moving scraper module is shown in a cross-section in FIGS. 4, 5, and 7.

In FIG. 3, the blade (see 221 in FIG. 4) is hidden by the bending guide plate 230. However, the position can be seen, as in FIG. 6, when the bending guide plate 230 is separated. The exploded view of FIG. 6 will also be referred to when the blade 221 is described.

The first body 210 of the moving scraper module 200 is connected to the guide described above and moves in parallel with the supporting plate 100. The first body 210, for example, may be a structure such as a metallic frame and can support the first elevator 220 and the blade 221 connected to the first elevator 220 on the guide such that the first elevator 220 and the blade 221 can move up and down. The first body 210 may have various shapes and structures that can move along the guide. Accordingly, the first body 210 may be changed in various shapes other than the shape shown in FIG. 3. A chain-shaped cable guide for wiring, etc. may be disposed on the outer surface of the moving scraper module 200.

The first body 210 moves in parallel with the supporting plate (see 100 in FIG. 2) and applies pressure in the same direction to push the blade (see 221 in FIG. 4) between the glass plate (see A1 in FIG. 1) and the stacked film (see A2 in FIG. 1). Accordingly, it is possible to increase the structural stability by connecting the first body to at least two pairs of different guide bars. For example, the first body 210 may be connected to at least two pairs of guide bars that are in parallel with the supporting plate 100 and spaced apart from each other, one of the pairs disposed higher than the blade 221 and the other disposed lower than the blade 221.

The first body 210 may be slidably coupled to the first guide bar (see 410 in FIGS. 1 and 2) through a first slider 211 formed at a side, and may be slidably coupled to the second guide bar (see 420 in FIGS. 1 and 2) through a second slider 212 formed at another side. As described above, the guide bars may be formed in pairs, and each sliders formed at the first body 210 may also be formed in pairs at positions corresponding thereto. In particular, as shown in the figures, the first slider 211 is disposed over the blade 221 and the second slider 212 is disposed under the blade 221, so supporting points that support the first body 210 (or supporting points that support the blade in the same way) may be formed over and under the blade 221 by the first guide bar 410 and the second guide bar 420 coupled to the sliders, respectively. Accordingly, the blade 221 can be very stably fixed while the blade moves into between the stacked film A2 and the glass plate A1.

The first elevator 220 is coupled to the first body 210 to be movable up and down. The blade 221, as shown in the figure, is disposed over the supporting plate 100 and connected to the first elevator 220, so the height of the blade 220 changes with respect to the supporting plate 100 when the first elevator 220 is operated. That is, the blade 221 is fixed to the first elevator 220 and changes in height together with the first elevator 220. The first elevator 220 may also be a structure such as a metallic frame and may be formed in various shapes that can fix the blade 221. For example, a first elevation actuator 214 that vertically contracts and stretches (i.e., perpendicular to the supporting plate horizontally disposed) may be disposed between the first elevator 220 and the first body 210, so it is possible to change the heights of the first elevator 220 and the blade 221 by contracting and stretching the first elevation actuator 214. The first elevation actuator 214, for example, may be a linear actuator having a structure of which both ends change in length, and the linear actuator, for example, may be achieved in various types such as a ball-screw device coupled to a stepping motor and a hydraulic cylinder. If necessary, a first elevation guide 214a (e.g., which may be composed of a vertical guide and a slider coupled thereto) that guides vertical movement may be disposed between the first body 210 and the first elevator 220, thereby being able to increase stability of elevation.

The blade 221 may be disposed at an appropriate position on the first elevator 220. For example, when the entire first elevator 220 is positioned over the supporting plate 100, the blade 221 may be disposed at the lower end of the first elevator 220 (see FIG. 4). This structure is shown in this embodiment. In more detail, the blade 221 may protrude at an angle from the lower end of the first elevator 220, and the end thereof may be machined to be pointed. The blade 221 may be firmly coupled to the first elevator 220 not to shake. The blade 221 may be a high-strength metallic blade, etc. A temperature adjuster 222 that increases the temperature of the blade 221 by heating the blade 221 may be disposed at a side of the blade 221, whereby it is possible to scrape the stacked film A2 with the blade 221 heated. The temperature adjuster 222, for example, may be a heating wire disposed close to the blade 221, and this structure makes it possible to effectively heat the entire blade 221. An insulator 223 made of an insulating material may be disposed at a necessary portion such as between the temperature adjuster 222 and the first elevation actuator 214.

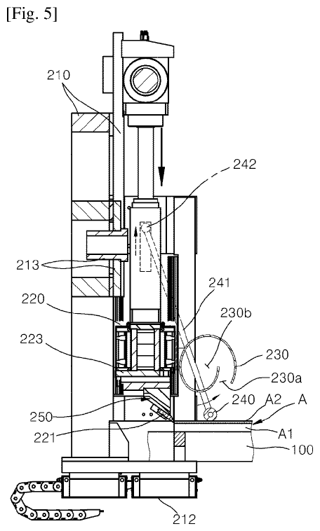

The bending guide plate 230 is disposed over the blade 221. The bending guide plate 230 is composed of a bending plate, is disposed over the blade 221, and rolls and keeps therein the stacked film A2 separated from the blade 221. Hereafter, the structure related to the bending guide plate 230 is described in more detail with reference to FIGS. 4 and 5.

The bending guide plate 230 has structure that immediately collects a stacked film A2 discharged over the blade 21 when the blade 221 cuts the stacked film A2 of a solar panel A. As shown in FIGS. 3 to 5, the bending guide plate 230 is composed of a bending plate and is formed by circularly bending the bending plate. The bending guide plate 230, particularly, may be formed by rolling the bending plate such that the radius of curvature gradually decreases.

Accordingly, an accommodation space 230b in which a stacked film is accommodated is formed inside the bending guide plate 230. The bending guide plate 230 is formed by rolling the bending plate and parts of the bending plate are spaced. Accordingly, a bent passage is formed therein along the bending plate. The opening 230a is formed at the inlet of the passage, as in FIG. 4, and the accommodation space 230b is formed at the center of the inside connected with the passage.

The opening 230a of the bending guide plate 230 between the parts of the bending plate is open downward toward the blade 221 disposed below the bending guide plate 230. Accordingly, it is possible to feed a stacked film, which is cut and discharged upward by the blade 221, inside using the downwardly open opening 230a. The bending guide plate 230, as shown in the figures, may be rolled once or more such that the internal accommodation space 230b is not exposed to the outside. In this case, not being exposed may mean that it is not exposed at least toward the opening 230a.

The bending guide plate 230 is rolled as described above, and may be longitudinally elongated. For example, as in FIG. 3, the bending guide plate 230 may be longitudinally elongated to have a length corresponding to the length of the blade 221. The bending guide plate 230, for example, may be a metallic bending plate, but may be made of other materials, if necessary. The bending guide plate 230 may be made of various materials that can be machined in a roll shape.

The bending guide plate 230 may be fixed to the moving scraper module 200. Preferably, the bending guide plate 230 may be disposed at a side of a first elevator 220 over the blade 221. The bending guide plate 230 is installed such that the opening 230a is open downward toward the blade 221, and the detailed position, or the size (or diameter) and the radius of curvature may be appropriately adjusted. The bending guide plate 230 may be fixed using fixing structures of various shapes, and may be installed through thread-fastening, etc. The method of installing the bending guide plate 230 may also not be specifically limited. If necessary, the bending guide plate 230 may be detachably formed.

A pressing roller 240 is disposed ahead of the blade 221. The pressing roller 240 can bring a stacked film into close contact with a glass plate such that the stacked film does not come off by pressing the stacked film between the blade 221 and the moving pressing modules (see 300a, 300b, and 300c in FIG. 1). The pressing roller 240, for example, may be connected to a support 241, etc., and disposed movably at a side of the moving scraper module 200.

An elevation shaft 242 that fixes the support 241 rotatably to the moving scraper module 200 may be formed at the end of the support 241 supporting the pressing roller 240. The elevation shaft 242 is supported by a compression spring (not shown) that is compressed up and down, whereby it can be elastically moved up and down. Accordingly, the pressing roller 240 can rotate around the elevation shaft 242 and a height can also be adjusted with up-down movement of the elevation shaft 242.

Accordingly, for example, when the first elevator 220 is moved down as in FIG. 4, the elevation shaft 242 is moved up in the opposite direction as in FIG. 5, and the position of the pressing roller 240 can be correspondingly adjusted. Further, since the pressing roller 240 can be rotated around the elevation shaft 242, the pressing roller 240 can press the stacked film A2 while rotating to a side in correspondence to up-down movement of the first elevator 220. For example, a torsion spring (not shown) that generates torque at the elevation shaft 242 to press the pressing roller 240 toward a solar panel may be applied to the elevation shaft 242. By using the pressing roller 240, it is possible to prevent the stacked film A2 from coming off by pressing the stacked film A2 even between the moving pressing modules 300a, 300b, and 300c and the blade 221.

The gas spray 250 may be formed between the blade 221 and the bending guide plate 230. Referring to FIG. 4, the gas spray 250 may be formed over the blade 221 of the first elevator 220. The gas spray 250 may include a structure that can spray a pressing gas B, and if necessary, may include a temperature control structure, etc. The gas spray 250 sprays gas to a stacked film passing through between the blade 21 and the bending guide plate 230, thereby being able to cool the stacked film.

A structure of the gas spray 250 is exemplified in FIG. 4. The gas spray 250 may be formed in a structure like a kind of nozzle that passes and sprays a pressing gas B to the blade 221. A supply structure (not shown) that supplies a pressing gas B may be connected to a side of the gas spray 250, and this supply structure, for example, may include a gas supply pipe, a compressing gas supply unit (e.g., pump, etc.), etc. The gas spray 250 can spray gas cooled through the supply structure. However, if necessary, it may include therein a temperature control structure (not shown) that can cool gas. The gas supply structure, etc. may be appropriately disposed using an internal space of the housing.

That is, a stacked film heated by heat from a heating unit (see 322 in FIG. 9) to be described below is cooled using the gas sprayed from the gas spray 250, thereby enabling the stacked film to recover elasticity without getting soft. Preferably, the gas spray 250 can spray gas at a temperature below the melting point of a stacked film. As described above, when the temperature of a stacked film is adjusted by the gas spray 250, the stacked film is discharged upward with appropriate elasticity, so the stacked film can be more easily inserted into the bending guide plate 230 over the blade 221 (see the operation in FIGS. 11A to 11E).

Further, the gas spray 250 can guide a stacked film to the opening 230a of the bending guide plate 230 by pressing the stacked film using the pressing gas B sprayed as in FIG. 4 (see the operation in FIGS. 11A to 11E). That is, the gas spray 250 can give elasticity by cooling a stacked film at a temperature below the melting point of the stacked film and can also adjust the direction in which the stacked film is bent by the pressure of gas. For example, this can be achieved by adjusting the spray pressure or the spray direction of the pressing gas B. When the gas spray 250 having this function is used, it is possible to more effectively insert a stacked film separated from the blade 221 into the bending guide plate 230 through the opening 230a of the bending guide plate 230.

A slit (251 in FIG. 6) may be formed along and parallel with the blade 221 at the end of the gas spray 250. The slit 251 may be elongated in the longitudinal direction in which the blade 221 extends. The gas spray 250 can spray a pressing gas to the entire space corresponding to the extended length of the blade 221 through the slit 251. By using this structure, it is possible to roll and collect a stacked film. The detailed operation will be described in more detail below.

Hereinafter, the method of adjusting the position of the blade is described in more detail with reference to FIGS. 6 and 7. FIG. 6 is an enlarged view in which the bending guide plate and the pressing roller are removed to show the blade. The following description is provided without the bending guide plate and the pressing roller for convenience.

Meanwhile, the height of the blade 221 can be very precisely adjusted by the load cell 110 that Senses load. Specifically, the load cell 110 is disposed under a solar panel (see A in FIG. 7) at a start position where the blade 221 starts to come in contact with the solar panel A. Further, there may be provided a controller 500 that brings the blade 221 in close contact with the solar panel A by moving down the first elevator 220 from the start position in cooperation with the load cell 110 and that adjusts the position of the blade 221 by controlling the operation of the first elevator 220 in accordance with at least any one of the magnitude and the variation of load sensed by the load cell 110. The controller 500 may be connected to the load cell 110 such that electrical signals can be transmitted therebetween, and may also be connected to the first elevation actuator 214 such that electrical signals can be transmitted therebetween. This connection includes both of wired connection and wireless connection. The controller 500, for example, may be a computer device including a Central Processing Unit (CPU), and the computer device may include a Programmable Logic Controller (PLC), etc. The controller 500 may be installed at an appropriate position in the housing.

Since the start position is the position where the blade 221 starts to come in contact with the solar panel A, it may be the same as the position where disassembling is started. Referring to FIG. 7, the start position, for example, may be a position where the blade 221 comes in contact with an end of the solar panel A or slightly overlaps the end. The start position is a position where the blade 221 can press the solar panel A when moving down, and may be the outermost position of the solar panel A. The start position can be artificially determined as a position where disassembling is started, so it may be appropriately changed, if necessary. However, in any case, the blade 221 can come in contact with the solar panel A at the start position. The load cell 110 is disposed under the solar panel A at the start position. The load cell 110 may be positioned at the same height as the supporting plate 100 and may be installed at an end of the supporting plate 100. For example, it may be possible to form a space by partially cutting the supporting plate 100 and dispose the load cell 100 in the space to be in contact with the solar panel A.

Accordingly, the load cell 110 can immediately sense load applied from above the solar panel A and a change of the load while being in contact with the bottom of the solar panel A. The operation of adjusting the position of the blade 221 by the load cell 110 and the controller 500 is described in more detail hereafter with reference to FIG. 7. First, the moving scraper module 200 can move along the guide to the start position. FIG. 7 shows the moving scraper module 200 at the start position. However, this operation is not necessary, and may not be needed depending on situations. For example, when the retreat position (e.g., the position in FIG. 2) is different from the start position (i.e., when the blade does not immediately come in contact with the solar panel even though it moved down), this prior operation may be required. However, when the retreat position is appropriate and the same as the start position, it is possible to bring the blade 221 in contact with the solar panel A by immediately moving down the blade 221, so there is no need for a specific prior operation, It is possible to perform the prior operation or not by appropriately considering various situations, for example, when the size of the solar panel A is partially changed or the movable range of the moving scraper module 200 is relatively large.

Since the blade 221 can come in contact with an end of the solar panel A at the start position, the controller 500 moves down the first elevator 220 at the start position, as shown in FIG. 7. The controller 500 can move down the first elevator 220 by stretching the first elevation actuator 214. Accordingly, the blade 221 connected to the first elevator 220 presses the solar panel A to apply pressure, which results in a change in the load value that the load cell 110 senses. The sensed load is immediately transmitted to the controller 500.

The controller 500 controls the operation of the first elevator 220 in accordance with the transmitted load value. The controller 500 can change the position of the first elevator 220 by transmitting a control signal to the first elevation actuator 214 in accordance with the load value. In particular, the controller controls the operation of the first elevator 220 and adjusts the position of the blade 221 in accordance with at least any one of the magnitude and the variation of the load sensed by the load cell 110. The blade 221 comes in contact with the outer surface of the stacked film A2 first and gradually comes close to the glass plate A1 while moving down. The blade 221 easily passes through the section corresponding to the stacked film A2 where density is low and deformation is easy, but receives large resistance as it comes close to the glass plate A1. Accordingly, the more the blade 221 comes close to the glass plate A1, the more the load sensed by the load cell 110 rapidly increases and the more the variation of the load quickly increases. Accordingly, the controller 500 can stop moving down the first elevator 220 and stop the blade 221 at the corresponding position, for example, when the load sensed by the load cell 110 reaches a set value or the variation (e. g., per unit time) of the load reaches a set value.

The controller 500, for example, may have a control program that performs the control operation through corresponding calculation therein. The controller 500 can perform the control by loading the control program. It is possible to very accurately position the blade 221 on the surface of the glass plate A1 by appropriately setting the upper limit of at least any one of the magnitude and variation of load. For example, it is possible to accumulate in advance data through tests on several solar panels A and derive appropriate set values from the data. It is also possible to update appropriate set values in an adaptable manner with data obtained through repeated work. Through this control, as shown in FIG. 7, the blade 221 can be stopped with the end thereof actually moved up by the thickness C of the glass plate A1 from the supporting plate 100.

The moving scraper module 200, as described above, adjusts the height of the blade 221 at the start position, and cuts the stacked film A2 while immediately moving in parallel with the supporting plate 100. Adjusting the height of the blade 221 and moving forward the blade 221 can be actually continuously performed without stop. Even if the prior operation for moving from the retreat position to the start position shown in FIG. 7 is required, a corresponding operation can be continuously performed. Accordingly, the moving scraper module 200 can perform the operation of moving down the blade 221 to the surface of the glass plate A1 and scraping the stacked film A2 while moving forward through one sequence while actually moving. The moving scraper module 200 can be operated in this way. The operation of the entire apparatus including the above operation will be described again in detail below.

FIG. 8 is an enlarged view of a moving pressing module of the solar panel disassembling apparatus of FIG. 1, and FIG. 9 is a cross-sectional view showing the internal structure of the moving pressing module of FIG. 8.

The moving pressing modules 300a, 300b, and 300c are described with reference to FIGS. 1, 2, 8, 9. First, the entire arrangement structure of the moving pressing modules 300a, 300b, and 300c is described. The moving pressing modules 300a, 300b, and 300c include a second body 310 connected to a guide and moving in parallel with the supporting plate 100, a second elevator (see 320 in FIG. 8) coupled to the second body 310 to be movable up and down and moving up and down perpendicular to the movement direction of the second body 210, and a pressing unit (see 321 in FIGS. 8 and 9) disposed over the supporting plate 100, connected to the second elevator 320, and changing in height with respect to the supporting plate 100 when the second elevator 320 is operated. Further, the moving pressing modules 300a, 300b, and 300c are disposed forward in the forward movement direction of the moving scraper module 200 (in the direction of the arrow in right in FIG. 10). According this configuration, when the moving scraper module 200 is moved forward, it is possible to align a stacked film (see A2 in FIG. 1) by pressing the stacked film using the pressing unit 321 ahead of the moving scraper module 200. In detail, the moving pressing modules 300a, 300b, and 300c can be connected and moved with the third guide bar 430 of the guides described above, and as shown in the figures, a plurality of moving pressing modules may be continuously disposed forward in the forward movement direction of the moving scraper module 200.

The moving pressing modules 300a, 300b, and 300c are substantially the same in that each of them includes a second body 310, a second elevator 320, and a pressing unit (see 321 in FIGS. 8 and 9). Further, they are substantially the same also in that they include a heating unit (see 322 in FIGS. 6 and 7) that guides thermal deformation of the stacked film A2 by heating the outer surface of the stacked film A2. However, any one moving pressing module 300a that are closest to the moving scraper module 200 may be partially different in that it includes a gap control rod (see 313 in FIG. 8) to adjust the gap from the moving scraper module 200. For example, when a single moving pressing module is provided, the moving pressing module may include the gap control rod 313.

The moving pressing modules 300a, 300b, and 300c may be formed not to be connected to the driving shaft 440 described above, and accordingly, they may not be directly supplied with a driving force from the driving structure. The moving pressing modules 300a, 300b, and 300c are in contact with the moving scraper module 200, so when the moving scraper module 200 is moved forward, they can be pushed by the moving scraper module 200. Accordingly, the forward operations of the moving scraper module 200 and the moving pressing modules 300a, 300b, and 300c are substantially synchronized. However, the present disclosure is not necessarily limited to this configuration, and if necessary, it is possible to move the moving pressing modules 300a, 300b, and 300c by providing a driving force to them. Though not shown, the moving pressing modules 300a, 300b, and 300c may be connected to each other through a chain, etc., and accordingly, they can move together even when they move opposite to the forward movement direction. As described above, the moving scraper module 200 can be fully retreated to the position shown in FIG. 2 before it is operated, and the moving pressing modules 300a, 300b, and 300c can be prepared substantially in close contact with the moving scraper module 200 by moving immediately in front of the moving scraper module 200, as shown in FIG. 2. Thereafter, the moving scraper module 200 pushes and moves forward the moving pressing modules 300a, 300b, and 300c together while moving forward.

The structural features of the moving pressing modules are described in more detail with reference to FIGS. 8 and 9. The actual features of the moving pressing modules are all included in the moving pressing module 300a closest to the moving scraper module of a plurality of moving pressing modules (see 300a, 300b, and 300c in FIGS. 1 and 2), so the detailed structure is described on the basis of the moving pressing module 300a.

Other moving pressing modules (300b and 300c in FIGS. 1 and 2) may be understood as equally to include other configurations except for the gap control rod 313.

The second body 310 of the moving pressing module 300a, for example, may be a structure such as a metallic frame. The second body 310 can support the second elevator 320 and the pressing unit 321 connected to the second elevator 320 on the guide such that they can move up and down. The second body 310 may have various shapes and structures that can move along the guide. Accordingly, the first body 210 may be changed in various shapes other than the shape shown in FIG. 8. A chain-shaped cable guide for wiring, etc. may be disposed on the outer surface of the moving pressing module 300a. The second body 310 is slidably coupled to the third guide bar (see 430 in FIGS. 1 and 2) through a third slider 311 formed at a side. Since guide bars are disposed in pairs, the slider bar 311 may also be disposed in pairs at corresponding positions. As described above, since the third guide bar 430 is positioned at the top of the housing 400, a supporting point can be formed at the upper end of the second body 310 by coupling to the third slider 311. This structure is advantageous to pressing and aligning a stacked film (see A2 in FIG. 1) by moving down the pressing unit 321.

The second elevator 320 is coupled to the second body 310 to be movable up and down. The pressing unit 321 is disposed over the supporting plate (see 100 in FIGS. 1 and 2) and connected to the second elevator 320, so the height thereof changes with respect to the supporting plate 100 when the second elevator 220 is operated. That is, the pressing unit 321 i fixed to the second elevator 320 and changes in height together with the second elevator 320. The second elevator 320 may also be a structure such as a metallic frame and may be formed in various shapes that can fix the pressing unit 321. A second elevation actuator 312 that vertically contracts and stretches (i.e., perpendicular to the supporting plate horizontally disposed) may be disposed between the second elevator 320 and the second body 310, so it is possible to change the heights of the second elevator 320 and the pressing unit 321 by contracting and stretching the second elevation actuator 312. The second elevation actuator 312, for example, may be a linear actuator having a structure of which both ends change in length. The linear actuator may be various actuators such as hydraulic cylinder. If necessary, a second elevation guide 312a that guides vertical movement (e.g., it may be composed of a vertical guide bar and a slider coupled thereto. The second elevation guide has a guide bar coupled to the second elevator and a slider fixed to the second body, whereby the entire guide bar can be moved up and down when the second elevator is moved) is disposed between the second body 310 and the second elevator 320, thereby being able to increase stability of elevation.

If necessary, a shock absorber 314 may be disposed in the forward movement direction of the second body 310. The shock absorber 314 is used to adjust the gaps between each of a plurality of moving pressing. Accordingly, a specific moving pressing module at the outermost side in the forward movement direction (e.g., 300c in FIGS. 1 and 2) may not need the shock absorber 314. The position of the shock absorber 314 can be appropriately adjusted, thereby being able to support appropriate positions of other moving pressing modules. The shock absorber 314 does not need to support the outermost sides of other moving pressing modules and may support the inner frames of the moving pressing modules, etc. It is possible to variously adjust the gap between the moving pressing modules by selecting positions. A plurality of moving pressing modules are enabled to move forward while maintaining appropriate gaps by increasing or decreasing the length of the shock absorber 314 by a required amount.

The pressing unit 321 may be disposed at an appropriate position at the second elevator 320. For example, when the entire second elevator 320 is positioned over the supporting plate 100, the pressing unit 321 may be disposed at the lower end of the second elevator 320 in a flat structure. The pressing unit 321 comes in contact with the stacked film A2 earlier than the blade (see 221 in FIG. 6) forward in the forward movement direction, thereby pressing and aligning the stacked film A2. As shown in FIG. 9, the pressing unit 321 may include a plurality of supporting rollers 321a spaced apart from each other in rolling contact with the outer surface of the stacked film A2. It is possible to press the stacked film A2 while moving using the supporting rollers 321a. However, the present disclosure is not necessarily limited to this configuration, and the pressing unit 321 may be modified in other types that can press and align the surface of the stacked film A2.

The moving pressing module 300a may include a heating unit 322 that induces thermal deformation of the stacked film A2 by heating the outer surface of the stacked film A2. That is, it is possible to induce the stacked film A2 to be at least partially deformed by applying heat while providing pressure through the pressing unit 321. Since pressure is applied by the pressing unit 321, the induced deformation may be enough to weaken the bonding between the stacked film A2 and a glass plate (see A1 in FIG. 1) even if thermal deformation is not excessively shown in the external appearance. That is, it is possible to make the stacked film A2 be easily separated by heating the stacked film A2 with the moving pressing module 300a before cutting it with the blade 221. Further, it is possible to remove any problems when the blade 221 enters the stacked film by pressing and aligning the stacked film with the pressing unit 321.

Referring to FIG. 7, the pressing unit 321 includes a plurality of supporting rollers 321a spaced apart from each other in rolling contact with the outer surface of the stacked film A2, and the heating unit 322 may be a heater that radiates heat to the space between the supporting rollers 321a in the pressing unit 321. That is, it is possible to simultaneously provide pressure and heat to substantially the same surface by disposing the heating unit 322 to overlap the pressing unit 321. The heater that is the heating unit 322, for example, may discharge at least any one of infrared beams or hot wind. For example, it is possible to provide heat in various ways such as a radiation heating type that discharges hot rays such as infrared beams to the space between the supporting rollers 321 or a convection heating type that heats the entire surrounding by feeding heated fluid. However, the manner of providing heat is not necessarily limited thereto, and other heating manners may also be freely used, if possible.

A gap control rod 313 may be disposed at the moving pressing module 300a. The gap control rod 313 is disposed between the moving scraper module (see 200 in FIGS. 1 to 3) and the moving pressing module 300a, thereby controls the gap between the blade 221 and the pressing unit 321. The gap can be set as necessary. Even though there is a gap between the blade 221 and the pressing unit 321, a stacked film are kept pressed by pressing the middle portion through the pressing roller described above (see 240 in FIGS. 4 and 5), thereby being able to prevent the stacked film from coming off. As shown in FIGS. 8 and 9, the gap control rod 313 may protrude from a side of the second body 310 which faces the moving scraper module 200, and may have a shock-absorbing structure at the end thereof. It is also possible, if necessary, to change the length of the gap control rod 313. The gap control rod 313 is not necessarily formed at the moving pressing module 300a, so it may be formed at the moving scraper module 200 in another embodiment. Hereafter, a solar panel disassembling operation of the present disclosure is described in more detail with reference to FIGS. 10 to 12.

FIG. 10 is a view showing an operation of disassembling a solar panel by the solar panel disassembling apparatus of FIG. 1, and FIGS. 11A to 11E are views showing in more detail an operation of the bending pressing plate in the disassembling operation of FIG. 10. FIG. 12 is a view showing an operation after disassembling a solar panel by the solar panel disassembling apparatus of FIG. 1. Note that main components are all shown in cross-sectional views in the section a (see FIGS. 10 and 12) in which a solar panel is positioned in order to more clearly show the disassembling process.

According to the configuration described above, the solar panel disassembling apparatus 1 automatically disassembles a solar panel A while operating as follows. Disassembling is described hereafter with reference to FIG. 10. The moving scraper module 200 brings the blade 221 in contact with the solar panel A by moving down the blade 221 at the start position (which is the same as the above description, see FIG. 7) and then moves forward. As described above, the blade 221 can be controlled to be stopped with the end on the surface of the glass plate A1 at the start position by the load cell (see 110 in FIGS. 6 and 7) and the controller (see 500 in FIGS. 6 and 7). That is, the blade 221 can cut the stacked film A2 with the end accurately positioned at the bonding position of the glass plate A1 and the stacked film A2.

As described above, when the start position is the same as the retreat position of the moving scraper module 200, the moving scraper module 200 can move forward while immediately moving down the blade 221. However, since the retreat position and the start position may be different depending on situations, in this case, a prior operation of slightly moving the moving Scraper module 200 from the retreat position to the start position may be performed, as described above. This may depend on situations. The moving pressing modules 300a, 300b, and 300c are prepared substantially in close contact with the moving scraper module 200 in which the moving scraper module 200 has been retreated before operating. In this state, the second elevator 320 may be in contact with the stacked film A2 by automatically moving down (e.g., the second elevator 320 may be enabled to automatically move down by installing a sensor, etc. at the lower portion). Thereafter, when the moving scraper module 200 moves, the moving pressing modules 300a, 300b, and 300c are pushed and moved together (when a driving force is not separately provided to the moving pressing modules, they can be manually prepared, but the same operation can be automatically performed without limit when an appropriate driving structure is applied to the moving pressing modules).

FIG. 10 shows a corresponding forward movement. The moving scraper module 200 and the moving pressing modules 300a, 300b, and 300c move together in close contact with each other while they move forward, as shown in FIG. 10. When being in close contact, the gap between the blade 221 and the pressing unit (see 321 in FIG. 9) can be controlled by the gap control rod 313 described above. The shock absorber 314 can reduce the gap between the moving pressing modules by supporting the inner frames of the moving pressing modules. As described above, the moving pressing modules 300a, 300b, and 300c press and align the stacked film A2 with the pressing unit 321 ahead of the moving scraper module 200 and induce thermal deformation as well using the heating unit 322. Accordingly, the stacked film A2 is aligned flat in contact with the blade 221 with the bonding with the glass plate A1 weakened. The blade 221 can be heated and increased in temperature by the temperature adjuster 222 described above, thereby being able to more easily enter between the stacked film A2 and the glass plate A1. Accordingly, as shown in the enlarged view of FIG. 10, it is possible to cleanly separate the stacked film A2 from the glass plate A1 by cutting (or scraping out) the stacked film A2 from the glass plate A1.

In this case, the cut stacked film A2 is rolled and inserted into the bending guide plate 230 disposed over the blade 221. That is, it is possible to feed the stacked film A2 separated from the glass plate A1 and discharged over the blade 221 into the bending guide plate 230 rolled over the blade 221 and immediately collect the stacked film A2.

Since the plasticity of the stacked film A2 is increased by heat even though it has elasticity, it can be guided to the bending pressing plate 230 by appropriately changing the direction. In particular, the gas spray 250 described above can change the direction to be toward the opening 230a by pressing the stacked film A2 between the blade 221 and the bending guide plate 230 simultaneously with cooling (elasticity increased) the stacked film A2 by spraying the pressing gas B. The pressure of the gas that is sprayed as described above may also be appropriately controlled.

Referring to FIGS. 11A to 11E, a process of collecting a stacked film A2 using the bending guide plate 230 is shown in more detail. The steps are separated for description, and they are continuously performed in practice.

First, as in FIG. 11A, an end of a stacked film A2 cut by the blade 221 is moved up over the blade 221. Since the stacked film A2 is pressed by the pressing roller 240 disposed ahead of the blade 221 before coming in contact with the blade 221, the stacked film A2 comes in close contact with the glass plate A1. However, after being separated by coming in contact with the blade 221, the stacked film A2 is pushed by the blade 221 and moved up over the blade 221.

In this case, the gas spray 250 sprays the pressing gas B that cools the stacked film A2 below the melting point of the stacked film A2. The stacked film A2 is cooled and simultaneously pressed by the pressing gas B. Accordingly, the direction is changed to be toward the opening 230a by the gas pressure. As shown in the figure, it is possible to effectively guide the stacked film A2 into the opening 230a of the bending guide plate 230 disposed over the blade 221 using gas pressure.

Accordingly, as shown in FIGS. 11B and 11C, the cut stacked film A2 is inserted into the opening 230a of the bending guide plate 230. The stacked film A2 can naturally enter the opening 230a that is an inlet while elastically coming in contact with the rolled surface of the bending guide plate 230. Further, since the stacked film A2 is pressed toward the opening also by pressing by the gas spray 250, the stacked film A2 can easily enter the opening 230a that is the inlet of the bending guide plate 230.

As shown in FIG. 11D, the stacked film A2 that has entered the opening 230a is then rolled inside the bending guide plate 230 along the rolled structure of the bending guide plate 230. Since the stacked film A2 keeps being cut and is inserted into the bending guide plate 230 by forward movement of the blade 221, the stacked film A2 is deformed into a roll shape while being moved along a bent surface by the pressure that is applied into the bending guide plate 230. In this way, as in FIG. 11E, it is possible to roll and collect the stacked film A2 into the accommodation space 230b inside the bending guide plate 230.

Since the diameter of the bending guide plate 230 can be adjusted as necessary, it is possible in practice to roll and collect the entire cut £ stacked film A2 into the accommodation space 230b of the bending guide plate 230. Further, since the accommodation space 230b of the bending guide plate 230 is not substantially exposed to the outside by the rolled structure, there is no possibility that the stacked film A2 inserted therein is separated outside. As described above, it is possible to conveniently roll and collect the stacked film A2 using the bending guide plate 230 having a rolled structure.

Such a movement continues until the blade 221 reaches the second end of the solar panel A, and accordingly, the entire stacked film A2 can be cleanly separated and removed from the solar panel A.

Since the stacked film A2 is cleanly removed from the solar panel A while the forward movement of the moving scraper module 200 continues, only the glass plate A substantially remains behind the blade 221.

When the forward movement is finished and the stacked film A2 is completely separated, only the glass plate A1 remains on the supporting plate 100, as shown in FIG. 12. The moving scraper module 200 that finished moving forward retreats in the opposite direction. Simultaneously, the bending guide plate 230 collecting the stacked film A2 separated from the blade 221 is also moved together with the first elevator. However, the moving pressing modules 300a, 300b, and 300c can keep being moved forward by inertia, and the second elevator 320 can move up when departing from the supporting plate 100.

The stacked film A2 in the bending guide plate 230 is rolled, thereby being able to form a stacked film coil A2-1. The stacked film coil A2-1 inserted in the accommodation space in the bending guide plate 230 can be taken out through a side of the bending guide plate 230 after the moving scraper module 200 is returned to the initial position. Alternatively, it may be possible to separate the stacked film A2 with the bending guide plate 230 by making the bending guide plate 230 be detachable. As described above, it is possible to conveniently collect a stacked film by cutting, separating, and rolling the stacked film.

Accordingly, it is possible to very conveniently separate the solar panel (see A in FIG. 8) into the glass plate A1 and the stacked film coil A2-1. In particular, since the height of the blade 221 is automatically adjusted and the blade 221 is very accurately positioned at the bonding point between the stacked film and the glass plate, very clean disassembling is possible with little byproducts and it is possible to easily collect the stacked film using the rolled structure of the bending guide plate 230. As described above, it is possible to very conveniently and accurately disassemble a solar panel with the solar panel disassembling apparatus 1 of the present disclosure.

Although exemplary embodiments of the present disclosure were described above with reference to the accompanying drawings, those skilled in the art would understand that the present disclosure may be implemented in various ways without changing the necessary features or the spirit of the prevent disclosure. Therefore, the embodiments described above are only examples and should not be construed as being limitative in all respects.

The solar panel disassembling apparatus is highly applicable in the renewable energy industry, specifically for recycling operations. It allows for efficient separation of glass and film components of used solar panels, reducing waste and enabling material recovery. This contributes to sustainability and cost efficiency in solar panel manufacturing and waste management, making it a valuable asset for recycling facilities and manufacturers seeking to minimize environmental impact and embrace circular economy practices.

1. A solar panel disassembling apparatus configured to separate a glass plate by removing a stacked film from a solar panel including the glass plate and the stacked film including solar cells stacked on the glass plate, the solar panel disassembling apparatus comprising:
a supporting plate configured to support a bottom of the solar panel so that a top surface thereof is in contact with the glass plate;
a moving scraper module comprising a first body connected to a guide and configured for moving in parallel with the supporting plate, a first elevator coupled to the first body to be movable up and down and configured for moving up and down perpendicular to a movement direction of the first body, and a blade disposed over the supporting plate, connected to the first elevator, and configured for changing in height with respect to the supporting plate when the first elevator is operated, that the moving scraper configured to scrape the stacked film using the blade while moving forward in parallel with the supporting plate;
a moving pressing module comprising a second body connected to a guide and configured for moving in parallel with the supporting plate, a second elevator coupled to the second body to be movable up and down and configured for moving up and down perpendicular to a movement direction of the second body, and a pressing unit disposed over the supporting plate, connected to the second elevator, and configured for changing in height with respect to the supporting plate when the second elevator is operated, is the moving pressing module disposed forward in a forward movement direction of the moving scraper module, and configured to press and align the stacked film using the pressing unit ahead of the moving scraper module when the moving scraper module is moved forward; and
a bending guide plate comprising a bending plate, the bending guide plate disposed over the blade, and configured for rolling and keeping therein the stacked film separated from the blade.

2. The solar panel disassembling apparatus of claim 1, wherein the bending guide plate has an accommodation space in which the stacked film is accommodated at a center because the bending plate is rolled such that a radius of curvature gradually decreases.

3. The solar panel disassembling apparatus of claim 1, wherein the bending guide plate has an opening being open downward toward the blade between parts of the bending plate, and is rolled once or more, so the accommodation space is not exposed to the outside.

4. The solar panel disassembling apparatus of claim 1, further comprising a gas spray cooling the stacked film passing through between the blade and the bending guide plate by spraying gas to the stacked film.

5. The solar panel disassembling apparatus of claim 4, wherein the gas spray guides the stacked film to the opening of the bending guide plate by pressing the stacked film.

6. The solar panel disassembling apparatus of claim 5, wherein the gas spray sprays the gas at a temperature below a melting point of the stacked film.

7. The solar panel disassembling apparatus of claim 5, wherein the gas spray sprays the gas through a slit formed along and parallel with the blade.

8. The solar panel disassembling apparatus of claim 1, wherein the moving pressing module further includes a heating unit that induces thermal deformation of the stacked film by heating the outer surface of the stacked film.

9. The solar panel disassembling apparatus of claim 8, wherein the pressing unit includes a plurality of supporting rollers spaced apart from each other in rolling contact with the outer surface of the stacked film, and the heating unit is a heater that radiates heat to a space between the supporting rollers in the pressing unit.

10. The solar panel disassembling apparatus of claim 8, further comprising: a load cell that is disposed under the solar panel at a start position where the blade starts to come in contact with the solar panel; and a controller that brings the blade in close contact with the solar panel by moving down the first elevator at the start position and that adjusts the position of the blade by controlling the operation of the first elevator in accordance with at least any one of magnitude and a variation of load sensed by the load cell.
